(19) United States
(12) Patent Application Publication
(10) Pub. No.: US 2013/0104984 A1
(43) Pub. Date: May 2, 2013

(54) MONOLITHIC PHOTOVOLTAIC SOLAR CONCENTRATOR

(71) Applicant: Stefan Myrskog, Richmond Hill (CA)

(72) Inventor: Stefan Myrskog, Richmond Hill (CA)

(73) Assignee: MORGAN SOLAR INC., Toronto, ON (CA)

(21) Appl. No.: 13/703,281

(22) PCT Filed: Jun. 10, 2011
(86) PCT No.: PCT/CA2011/000693

§ 371 Date: Dec. 10, 2012

Related U.S. Application Data
(60) Provisional application No. 61/354,039, filed on Jun. 11, 2010.
(60) Provisional application No. 61/374,499, filed on Aug. 17, 2010.

(51) Int. Cl. H01L 31/0232

(52) U.S. Cl. CPC H01L 31/02327
USPC 136/259

(57) ABSTRACT

A photovoltaic solar collector and concentrator apparatus consists of a solid, one-piece, sun light transmitting, non-imaging optical element coupled to a photovoltaic cell. The photovoltaic solar collector and concentrator has an entry surface including focusing elements and an opposed surface including uncoated reflector elements. The focused sun light is directed by the reflector elements via total internal reflection directly towards the photovoltaic cell without any reflection from the entry surface. An additional redirecting element based on total internal reflection and integral with the collector and concentrator optical element is used to couple the sunlight from the reflector elements to a photovoltaic cell positioned in plane parallel to the entry surface.

### CROSS-REFERENCE TO RELATED APPLICATION

This application claims the benefit of U.S. provisional application No. 61/354,039, filed Jun. 11, 2010, and U.S. provisional application 61/374,499, filed Aug. 17, 2010, under 35 U.S.C.s. 119(e), which applications are herein incorporated by reference.

### FIELD OF THE INVENTION

The present invention relates to concentrating photovoltaic solar energy collection apparatus. More particularly this invention relates to a low concentration solar energy collection photovoltaic apparatus using a light guide based on total internal reflection.

### BACKGROUND OF THE INVENTION

Photovoltaic (PV) solar energy collection apparatus are used to generate electric power from solar energy. Flat panel collectors generally include PV cell arrays formed on semiconductor substrates (e.g., monocrystalline silicon, polycrystalline silicon or thin-films such as cadmium telluride). The electrical energy output from flat photovoltaic collectors is a direct function of the area of the array, thereby requiring large, expensive semiconductor substrates.

Concentrating solar collectors reduce the need for large semiconductor substrates by concentrating solar light using a variety of optical elements such as reflectors or lenses that focus and direct the sunlight onto a smaller area that is used to place a much smaller PV cell. In this way, concentrating solar collectors are generally more efficient and cost less than flat-panel collectors.

Depending on the ratio between the input solar collection area and the size of the output concentrated sunlight spot at the level of the PV cell, optical concentrators can provide low concentration such as 2×-10×-20× of and high concentration such as up to 500×-1000×-2000×

Low concentration photovoltaic solar collectors are known. Low concentration photovoltaic solar collectors using light guide optical elements are known. Low concentration photovoltaic solar collectors using light guide optical elements based on total internal reflection (TIR) are also known. Low concentration photovoltaic solar collectors based on TIR consisting of a solar focusing component and a separate light guide are also known. Reference is made in this regard to US 2011/0096426 to Ghosh and to WO 2010/033859 to Ford. In these two referenced designs the alignment issues between the separate focusing components and reflectors in the waveguide create efficiency problems in manufacturing and in operation. Monolithic or a single piece low concentration photovoltaic solar collectors using a light guide having focusing elements on an entry surface and mirror coated reflectors on a separate surface not based on TIR are also known. Reference is made in this regard to US 2007/0251568. In this design, the use of mirror coated reflectors becomes not only a manufacturing and a cost issue but also an output efficiency issue since the mirror coated layer has to have a high reflectance over the local solar spectrum at each location, it creates an inherent loss and is vulnerable to degradation. If the degradation differs between the individual concentrators of a panel, the total output of the panel will be decided by the lowest performance reflector.

A need exists for new and improved low solar photovoltaic concentrator that achieve not only higher performance but which are also simpler and cost-effective to manufacture, maintain, operate and service.

### SUMMARY OF THE INVENTION

This relates to

a non-imaging solar energy concentrator consisting of a solid, one-piece, light transmitting optical element, having an entry surface including focusing elements and a stepped surface opposed to the entry surface including light reflectors corresponding to the focusing elements and a solar cell coupled to the concentrator. According to an embodiment of the invention the sunlight reaching the solar cell is directly coupled onto the PV cell from the reflectors that are positioned relative to the focusing elements under an angle to ensure total internal reflection of the focused sunlight by the reflectors and thus without using a reflecting coating. According to another embodiment of the invention the sunlight reaching the solar cell is coupled onto the PV cell from the reflectors via an additional optical element that is part of the concentrator. According to another embodiment of the invention the additional optical element operates based on total internal reflection.

The solar cell may be a silicon or multi-junction photovoltaic (PV) cell.

### BRIEF DESCRIPTION OF THE DRAWINGS

The invention may be better understood with reference to the drawings, in which:

FIG. 1 is a schematic, isometric view of a linear solar concentrator and PV cell according to an embodiment of the invention;

FIG. 2 is a schematic, sectional view of the embodiment of FIG. 1, with selected light beams shown for the purpose of illustration;

FIG. 3 is an enlarged view of the part of FIG. 2 denoted by reference numeral 3,

FIG. 4 is a view similar to FIG. 1, with reference numerals added to show the dimensions of the first embodiment;

FIG. 5 is a schematic, isometric view of a two-sided linear solar concentrator and PV cells according to another embodiment of the invention;

FIG. 6 is a partial, schematic, sectional view of a linear solar concentrator according to another embodiment of the invention, with selected light beams shown for the purpose of illustration;

FIG. 7 is a partial, schematic, sectional view of a linear solar concentrator according to another embodiment;

FIG. 8 is a partial, schematic, sectional view of another embodiment, with some light beams shown for the purpose of illustration;

FIG. 9 is a partial, schematic, sectional view of a solar concentrator according to another embodiment with a horizontally oriented PV cell;

FIG. 10 is an isometric view of a linear solar concentrator according to another embodiment of the invention;

FIG. 11 is an isometric view of a circular solar concentrator according to another embodiment of the invention; and

FIG. 12 is a schematic, sectional view of a circular low concentration solar concentrator apparatus with a horizontally-oriented PV cell according to another embodiment of the invention, with selected light beams shown for the purpose of illustration.

FIG. 12 is a schematic, sectional view of a circular low concentration solar concentrator apparatus with a horizontally-oriented PV cell according to another embodiment of the invention, with selected light beams shown for the purpose of illustration.

FIG. 13 is a schematic, sectional view of a low concentration solar concentrator apparatus with a horizontally-oriented PV cell according to another embodiment of the invention, with selected light beams shown for the purpose of illustration.

### DETAILED DESCRIPTION OF EMBODIMENTS

### Definitions

As used herein, directional terms such as “upper,” “top,” “lower,” “bottom,” “above,” below,” “horizontal,” “vertical,” etc. are intended to provide relative positions for the purpose of description and are not intended to designate an absolute frame of reference.

The term “comprising” means including but not limited to the recited integer(s). The term “consisting of” means including only the recited integer(s) and no other additional elements.

“Angle of acceptance” means the maximum angle, relative to the light axis, at which the incident light beams may enter the system and for which the power generation is 90% of the maximum.

“Thickness” means the maximum dimension between first and second opposed surfaces of optical elements according to the invention. In the present drawings, the thickness is shown in the vertical dimension.

“Aspect ratio” means the ratio between the longest length of the top collecting surface of the optic to the thickness of the optical element. For circular embodiments of solar concentrators described herein, the longest length will be the diameter of the optical element.

“Collection area” is defined herein to mean the area of the solar concentrator that is normal to the incident solar radiation, including inactive portions thereof.

The term, “concentration ratio” means the ratio of the collection area to the area of the exit surface.

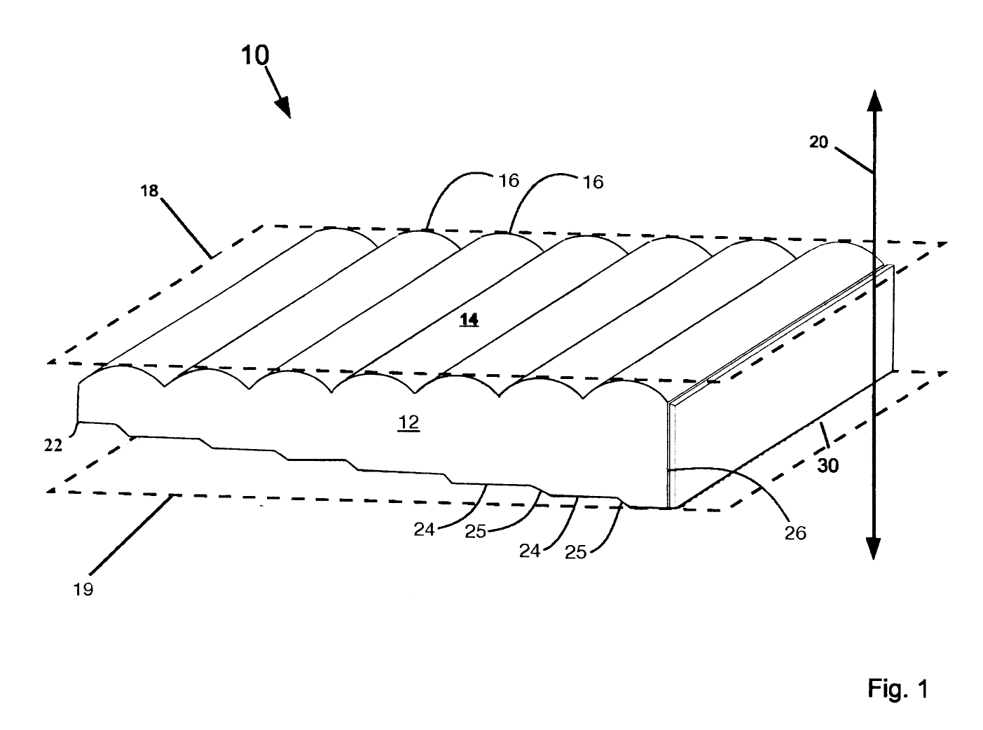

FIGS. 1, 2 and 3 show a non-imaging solar collector apparatus according to an embodiment of the invention designated generally by reference numeral 10. The apparatus comprises a solar concentrator consisting of a solid, one-piece, light transmitting optical element 12 made in this embodiment of a plastic material by injection molding. The optical element 12 is coupled to a solar cell in the form of a either a single or a multi-junction photovoltaic cell 30.

The optical element 12 comprises (i) an entry or an input surface 14 and a series of focusing elements 16 that together form a top collecting surface for collecting sunlight beams 17. As can be seen in FIG. 1, the focusing elements 16 are formed generally in plane 18 shown in chain dotted outline that is defined on one side axis 20 that is normal to the plane 18. In an embodiment of the invention focusing elements 16 extend linearly in a first direction with the rows being transversely spaced relative to the axis 20 in a second direction that is perpendicular to the first direction. Focusing elements 16 have a curved upper surface that can be spherical, cylindrical or free form. The curvature defined by a sag 27 whose value depends on the focal length of the focusing elements 16. A shorter focal length is preferred to reduce the thickness of the concentrator and thus being able to mold it faster.

The optical element 12 further comprises a stepped surface 22 opposed to the first surface 14, including a series of light reflecting steps 24 optically coupled and thus corresponding to the focusing elements 16.

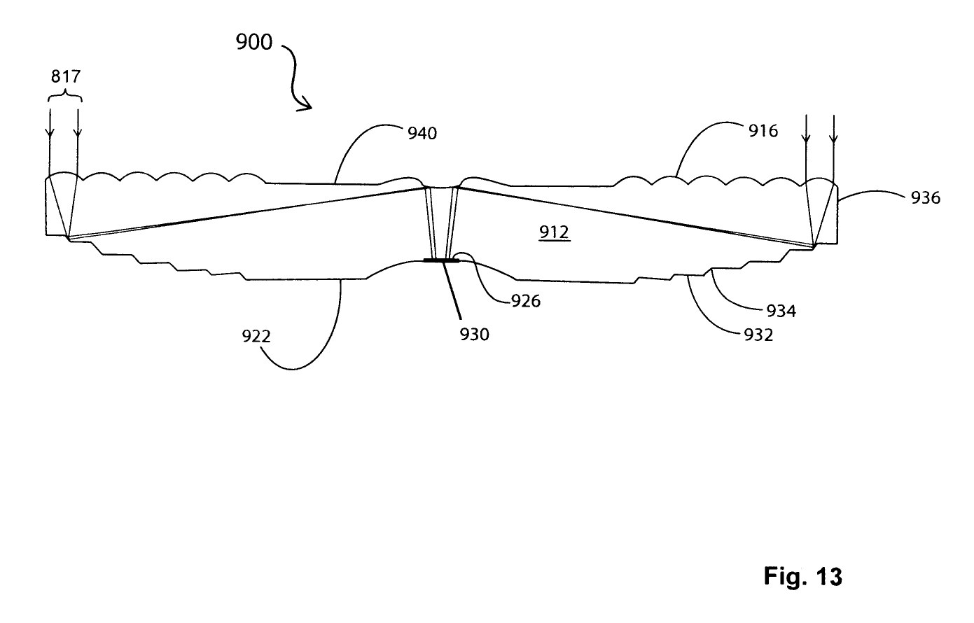

The entry surface of the focusing elements 16 in all the embodiments shown in FIGS. 1-13 can be one of a spherical, cylindrical, parabolic, hyperbolic or free form.

The reflectors 25 of the stepped surface 22 in all the embodiments shown in FIGS. 1-13 can be one of a flat, spherical, cylindrical, parabolic, hyperbolic or free form.

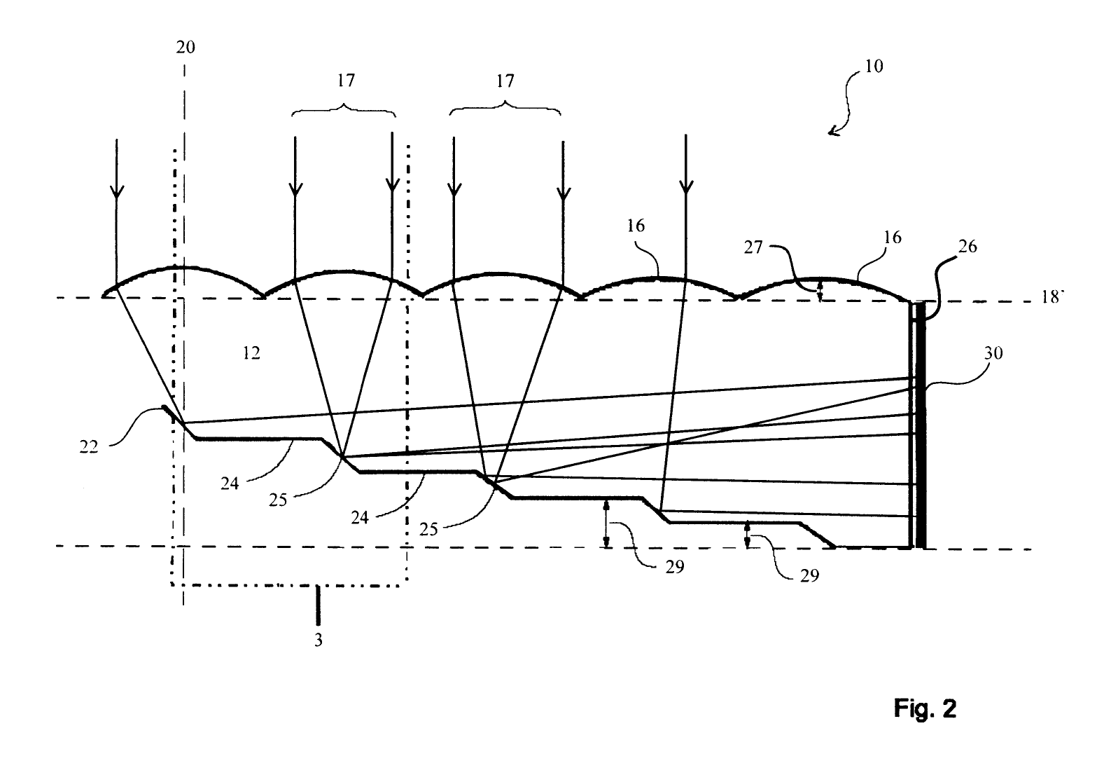

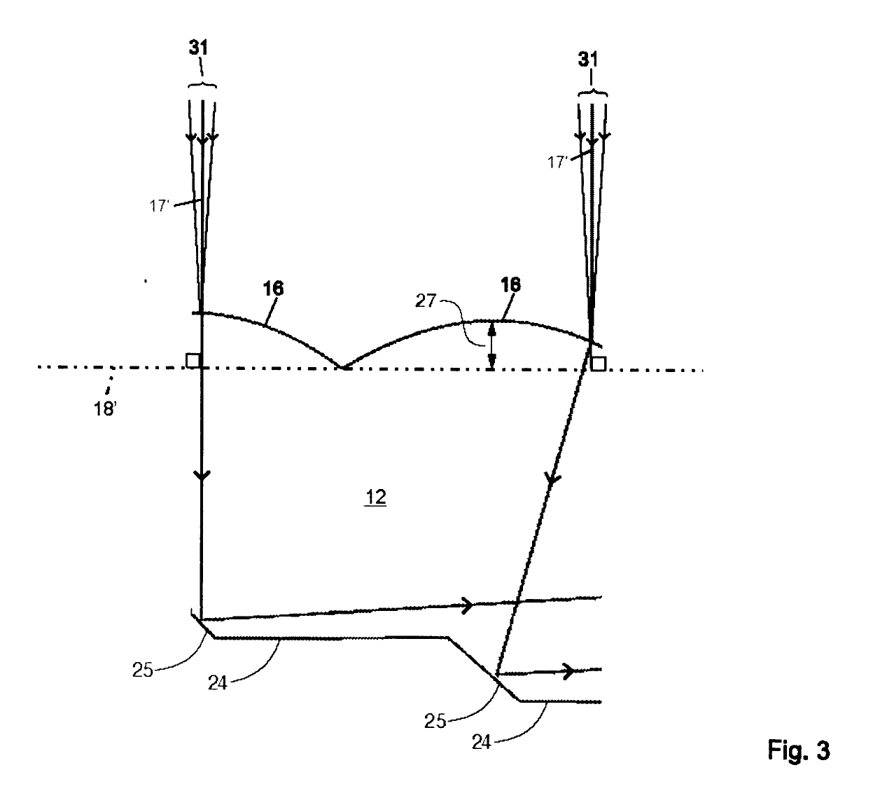

FIG. 3 is an enlarged view of the portion of the optical element 12 shown in FIG. 2 denoted by reference numeral 3. As seen in FIGS. 2 and 3, the stepped surface 22 includes reflectors steps 24 and reflectors 25 angled relative to the steps 25 by an angle that allow the total internal reflection (TIR) of the solar beams by the reflectors 25 with no light loss travelling towards a light output surface 26 by way of no additional reflections or bounces from the entry surface 14. In this embodiment, the angle of acceptance is about 1° from an axis normal to the plane 18. As shown in FIG. 3, the light beams 17 are normal to the plane 18 at zero degrees from the optical axis. The angle of acceptance is ½ the angular aperture shown by reference numeral 31 in FIG. 3. The concentrated sun light is directed to a solar cell in the form of a multi-junction photovoltaic (PV) cell 30. The PV cell 30 is attached to the light receiving region by convention means and converts light into electricity. The PV cell 30 can be coupled to other components of a solar collector apparatus (not shown) by known means.

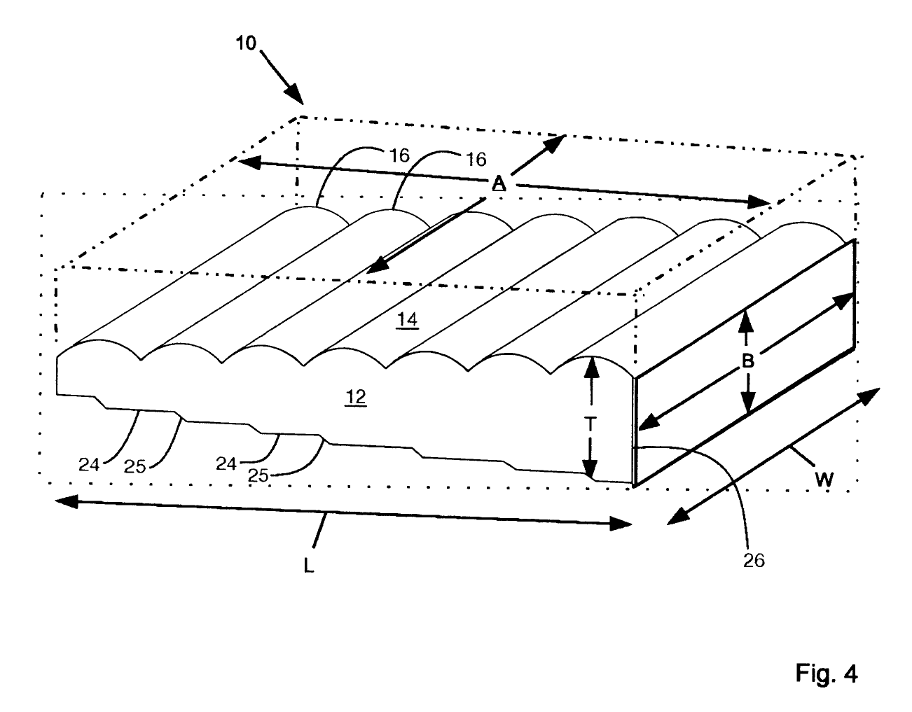

FIG. 4 illustrates the dimensions of the rectangular optical element 12, including the thickness “T”, length “L” and width “W” thereof. In this embodiment, the length may be from 20 mm to 900 mm, the width is about 10 mm to 500 mm, and the thickness is about 10 mm. Also, in this embodiment, the focusing elements 16 span the entire first surface 14 and therefore the entire upper surface of the optical element 12 functions as a collecting surface for light beams. In this embodiment, the collection area “A” is equal to L×W. Light beams incident on the entire first surface 14 is redirected by the reflecting steps 24 towards an area “B”=T×W that is smaller than area “A” to achieve a concentration ratio of A/B which, in this embodiment, is 5.

As is known in the art, “total internal reflection” occurs when the angle of a light beam incident on a boundary from a more optically dense medium to a less optically dense medium is greater than a critical angle θc given by:

$${θ}_{c} = arc sin ( \frac{{n}_{2}}{{n}_{1}} ) ,$$

where n₂ is the refractive index of the less optically dense medium, and n₁ is the refractive index of the more optically dense medium. The angle of incidence is measured with respect to the normal at the refractive boundary.

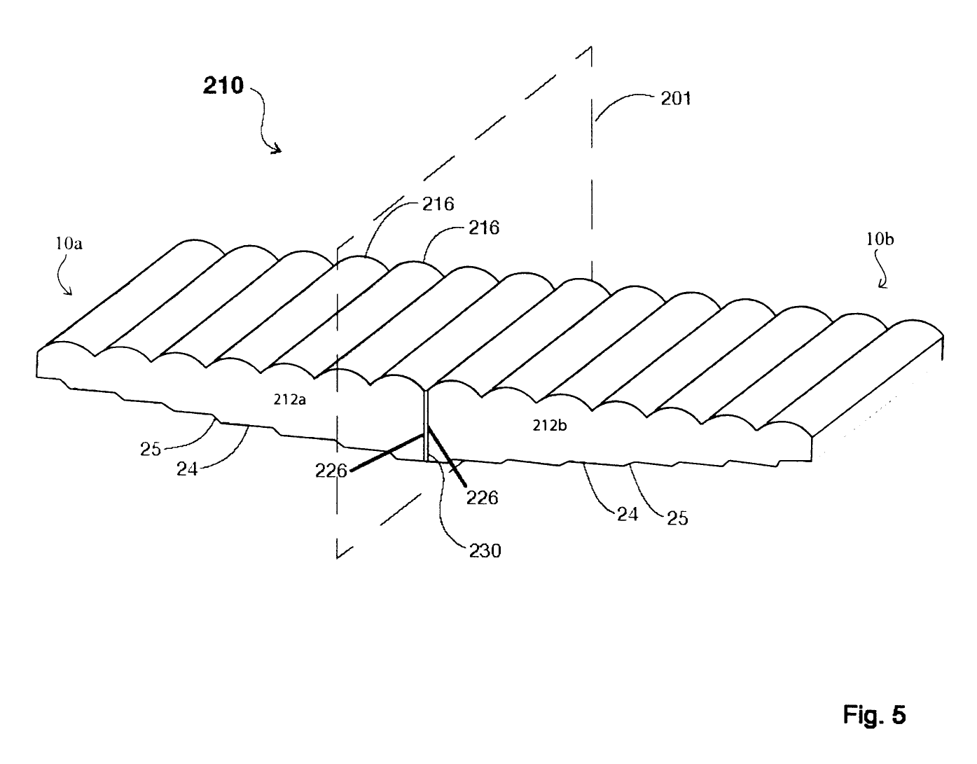

FIG. 5 shows another embodiment of the invention having a two-sided linear or composite non-imaging solar collector apparatus 210. The solar collector apparatus 210 comprises two solar concentrators 10a, 10b according to the first embodiment described above, placed together with two image mirrored regions 2126a, 212b thereof face-to-face. Two PV cells (not shown), one for each optical element 212a, 212b, are sandwiched between the two optical elements 212a, 212b for receiving concentrated light and converting it to electrical energy. Also a double face PC cell can be used. In some embodiments heat sinks are provided in contact with the PV cells. Very thin heat sinks using the heat pipe or a Peltier device are used.

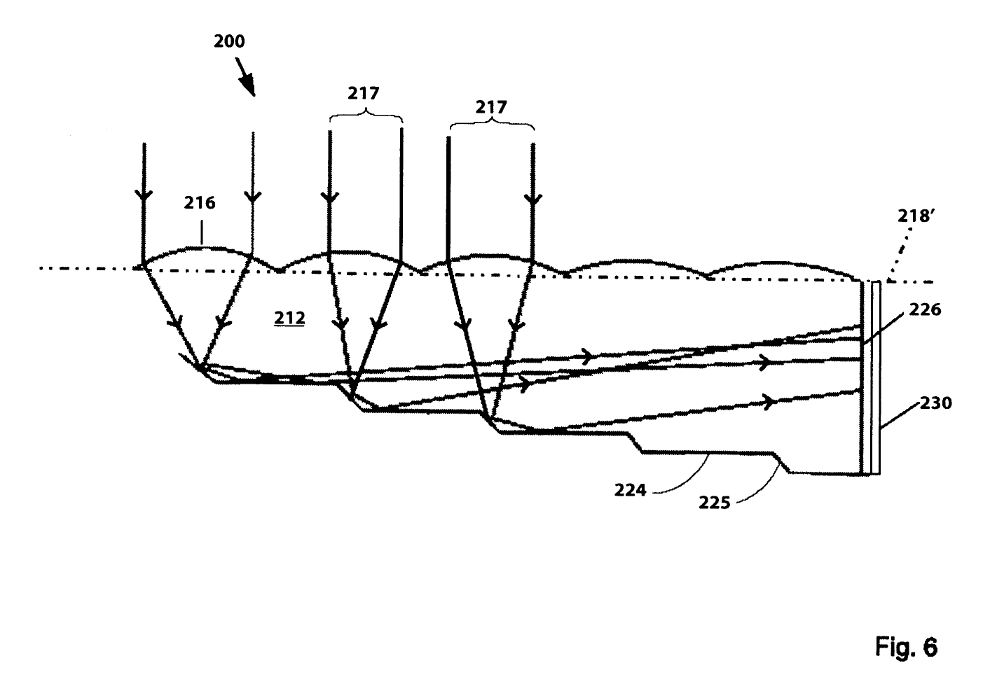

FIG. 6 is a partial, schematic, sectional view of a solar collector apparatus 200 comprising an optical element 212 according to another embodiment of the invention. The optical element 212 is sized and shaped to cause light within the optical element to experience two reflections at the stepped surface 622, namely a first TIR reflection by reflector 225 and a second TIR reflection at the step 224. This is done to relax the TIR constraints imposed on reflectors 225. This also allows a low index-of-refraction material to be used in that could not support the necessary change in angle from surface 225 using a single TIR reflection, but can be accomplished using two TIR reflections.

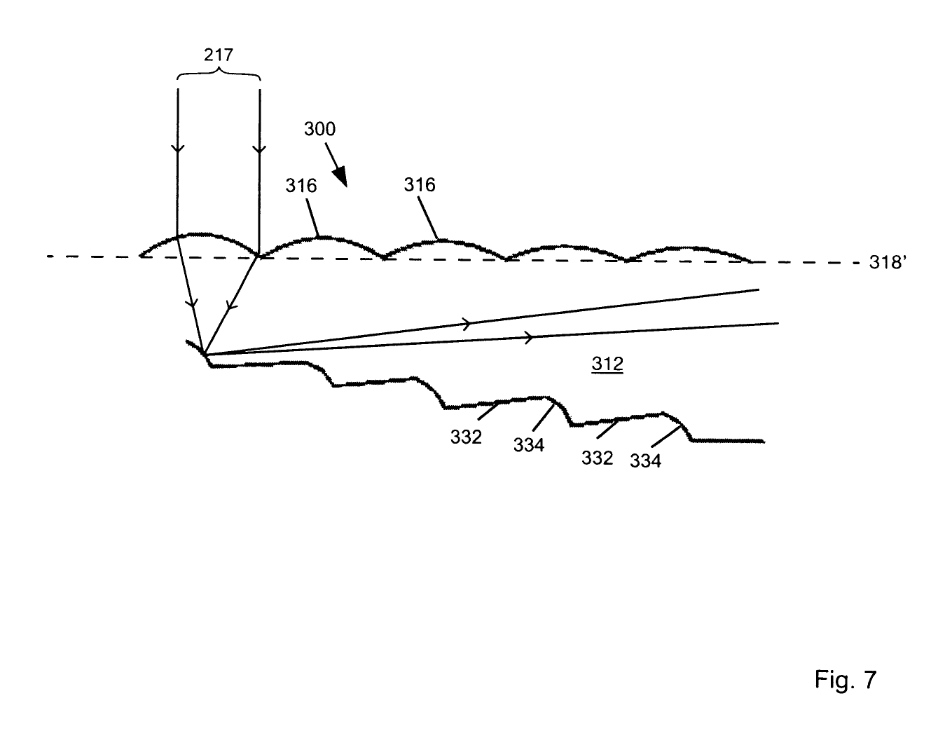

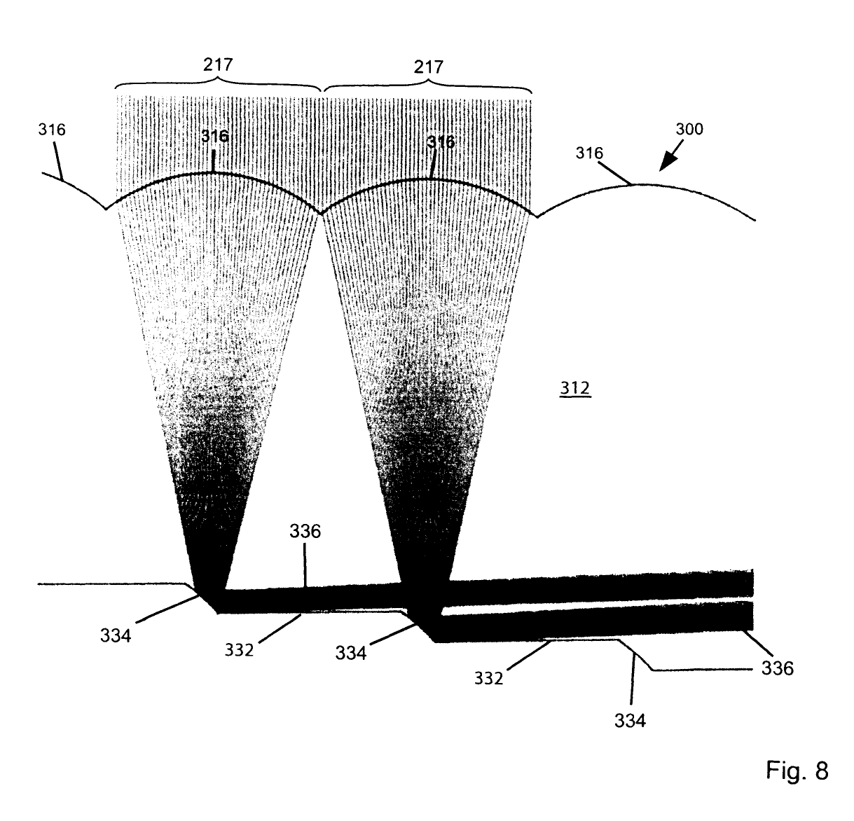

FIGS. 7 and 8 are partial, sectional views of a solar collector apparatus 300 comprising an optical element 312 according to another embodiment of the invention. Here, the optical element 312 has a series of linearly extending, transversely spaced rows of focusing elements 316 and a corresponding series of linearly extending, reflectors 334 having curved surface that are dimensioned to produce ray bundles 336, as shown in FIG. 8. The ray bundles can be collimated. In this embodiment steps 332 are inclined and not parallel with respect to plane 318′ that defines entry surface 314 of this concentrator.

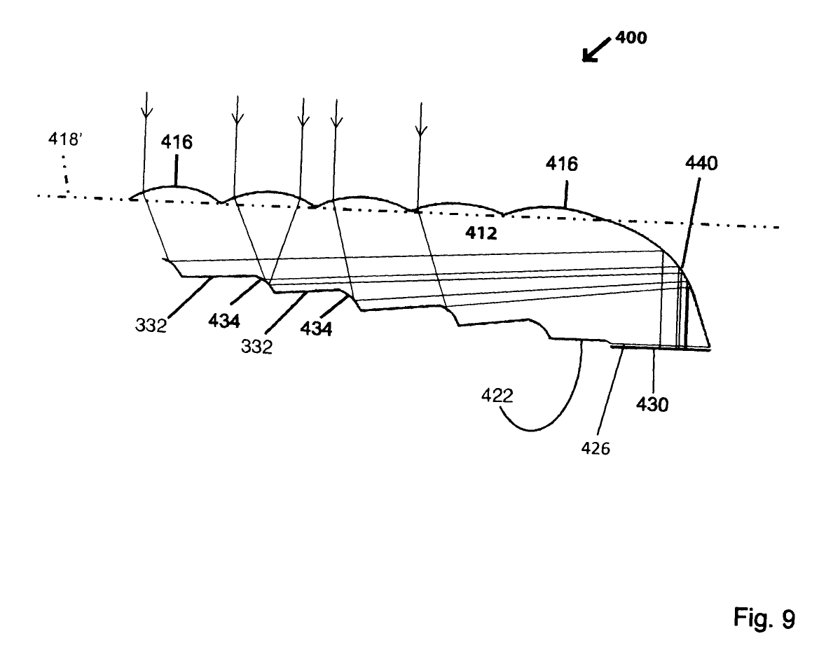

FIG. 9 is a partial, schematic, sectional view that illustrates an optical element 412 according to another embodiment of the invention that is a variation on the optical element 312 shown in FIGS. 7 and 8. The optical element 412 is similar to optical element 312 except that it has an additional TIR optical surface 440 that is curved to reflect light beams downwardly towards a horizontally-oriented exit surface 426 to which is attached a PV cell 430. The horizontally-oriented light exit surface 426 is parallel to a plane 418′ on which focusing elements 416 are generally formed and is integral with (i.e. a part of) the opposed stepped surface 422. As in the case of the other embodiments, the light reflected off the second reflecting surface 440 experiences total internal reflection in this embodiment. This embodiment can be made into either a linear or a circular solar concentrator. Circular solar concentrators are later in this specification.

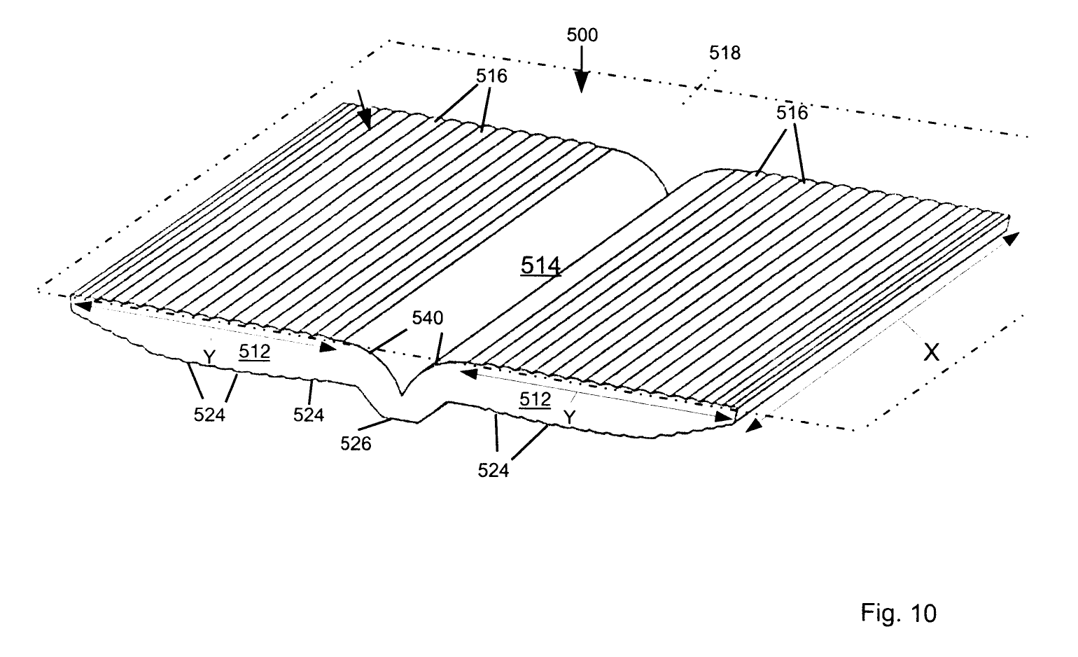

Referring now to FIG. 10, a linear solar collector apparatus 500 comprising a linear optical element 512 according to another embodiment of the invention is shown. Light beams (not shown) are received by rows of linearly extending, transversely spaced, focusing elements 516 formed on part of a first (upper) surface 514 that defines a collection surface. The part of the first surface formed into the focusing elements 516 is “active” in the sense that such part functions to refract and direct incident light on reflective steps 524. As in the case of the above described embodiments, light incident on the focusing elements 516 within a pre-defined angle of acceptance of less than 1° is refracted and directed on corresponding linearly extending light reflecting steps 524 where they are reflected with total internal reflection towards upper second reflecting surfaces 540. Here, the light experiences a second reflection down towards a light receiving region 526 lined with PV cells (not shown). Here too, the light receiving region 526 is a part of a second surface 522 that is opposed to and spaced from the first surface 514, and parallel to a plane 518 in which the focusing elements 516 are generally formed.

In this embodiment, the collection area is larger than the area of the focusing elements 516 normal to incident light, the latter being roughly equivalent to 2× the width “X” multiplied by transverse distance “Y” shown in FIG. 10. As also can be seen in FIG. 10, the light receiving region 526 has an area that is smaller than the area of the focusing elements whereby light incident on the focusing elements 516 is concentrated and directed on the light receiving region 526 and transmitted to one or more PV cells (not shown) for conversion to electricity.

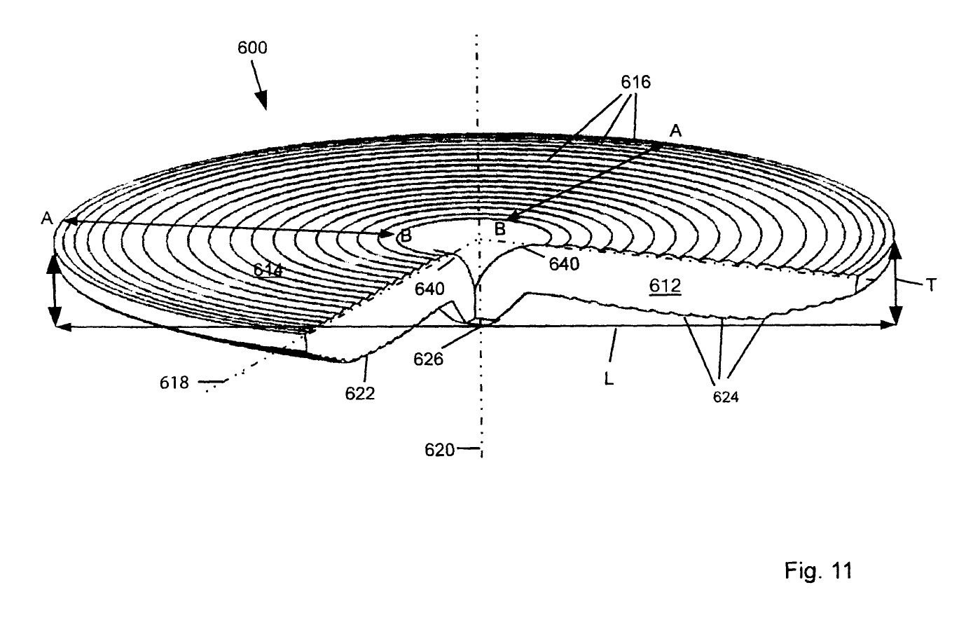

Optical elements according to the invention need not have linearly extending focusing elements. FIG. 11 illustrates a solar collector apparatus 600 comprising a circular optical element 612 according to a 7^{th} embodiment of the invention. The optical element 612 is generally symmetrical about an axis 620 shown in chain dotted outline which defines a plane 618 (shown partly in chain dotted outline). The optical element 612 has contiguous, rows of focusing elements 616 extending in the plane 618 and spaced transversely between A and B, as well as a series of light reflecting steps 624 formed by a second surface 622 opposed to a first surface 614 in which the focusing elements 616 are formed. As can be seen in this figure, both the focusing elements 616 and the light reflecting steps 624 form concentric rings about the axis 620. The axis 620 is central and normal to a concentrated light receiving region 626 that extends in a plane parallel to the plane 618 and is a part of the second surface 622. When in use, light beams (not shown) are refracted and directed by the focusing elements 616, reflected from the light reflecting steps 624 with total internal reflection towards a second annular upper reflecting surface 640 and reflected downwardly to the light receiving region 626 and transmitted to a PV cell (not shown).

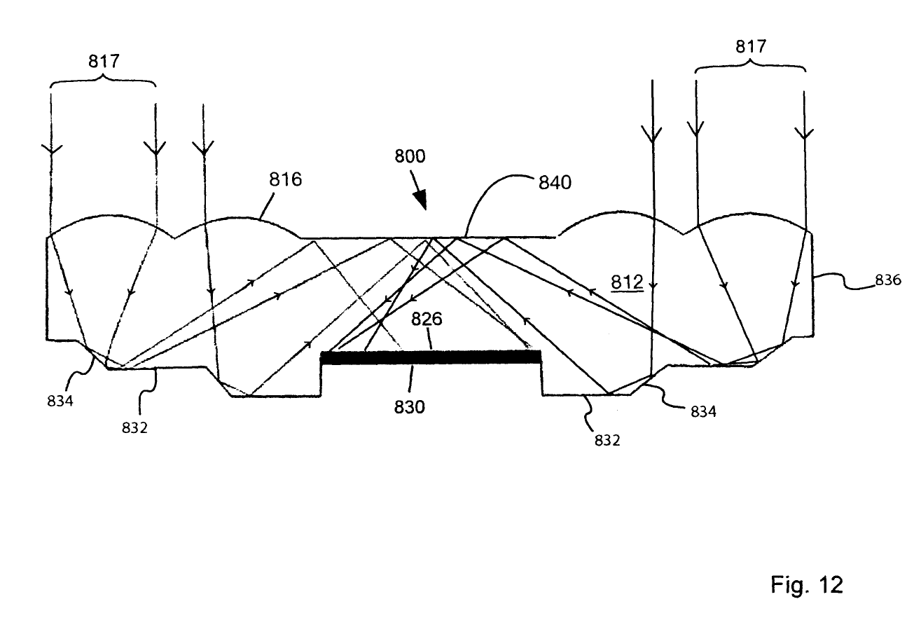

FIG. 12 is a schematic, sectional view of a circular low concentration solar collector apparatus 800 comprising an optical element 812 and a horizontally-oriented PV cell 830 according to an eighth embodiment of the invention, with selected light beams 17 shown for the purpose of illustration. The optical element 812 provides low concentration since the ratio of the collection area (first surface 814) to the exit surface (in the form of light receiving region 826) is low.

The shape of the focusing elements of embodiments according to the invention may be hyperbolic, parabolic, spherical, aspherical, parabolic, elliptical or any free-form. Likewise, the shape of the light reflecting steps may be straight, curved, elliptical, parabolic, hyperbolic or any free-form.

The dimensions of the optical element will depend on a number of factors including the size and shape of the focusing elements, manufacturing tolerances, and whether the element is linear or circular.

For linear embodiments, the length may range for example from 10 mm to 500 mm. The widths may range for example from 10 mm to 500 mm. The thickness of the output surface may range for example from 2 mm to 80 mm. The concentration ratio may range for example from 2 to 50. The aspect ratio may range for example from 2 to 50.

For example, one embodiment of a linear optical element according to the present invention has a thickness of about 4 mm, a length of about 60 mm, a width of about 100 mm and a concentration ratio of about 15.

Circular embodiments of optical elements according to invention will have diameters (i.e. lengths) ranging from 25 mm to 50 mm, 40 mm to 200 mm, or from 100 mm to 400 mm. The thickness may range from 1 mm to 3 mm, 2 mm to 5 mm or from 5 mm to 15 mm. The concentration ratio may range from 10 to 300, or from 5 to 20. The aspect ratio may range from 3 to 6, or from 5 to 10, or from 2 to 20.

Preferred embodiments are those designed to provide higher concentration ratios for more efficient power generation and to reduce the amount of material used and manufacturing costs.

The optical element may be made of any material that exhibits high optical clarity and can be made of glass, plastic (e.g. acrylic and polycarbonate), silicone, urethane and copolymers. Suitable materials that can be used to make the present optical elements having a low density and high index of refraction are disclosed in U.S. Pat. No. 5,288,669 to Grateau et al.

Optical elements according to the invention may be made by a variety of methods of manufacture including injection molding, compression molding, coining, sintering, machining, cold casting and hot casting. The actual method employed will depend on the material that is used as will be understood by the person of ordinary skill in the art. For example, plastics can be injection molded while glass can be compression molded.

Embodiments according to the invention are solid, one-piece units shaped and sized to reflect light internally without “free space” propagation, i.e. transmission of light beams through air downstream of the focusing elements 16 and upstream of the concentrated light receiving region of the optical element. In other words, there is only one refraction of light which occurs at the first surface that define the focusing elements. This serves to reduce energy losses occurring at the boundary of materials having different refractive indices. Each reflection occurring within the optical element is preferably but need not be with total internal reflection. It will be appreciated that minor variations in angles of reflecting surfaces are possible while still producing a commercially viable product. Nonetheless, total internal reflections within the optical element are preferred in order to minimize energy losses as the light travels through the optical element. It will be appreciated that some energy will be lost even in systems designed to provide total internal reflection due to absorption of energy by the material itself and minor defects in material surfaces caused by conventional manufacturing methods and tolerances.

Unlike the prior art documents such as US 2007/0251568 the embodiments of the invention described above in FIGS. 1 to 13 do not have reflective (e.g. mirrored) coatings on the reflectors 25, the steps 24 or redirecting element 440 and the equivalent parts in all the embodiments. The mirror coated surfaces of U.S. Pat. No. '568 will degrade in the presence of sun light over time and will lead to lower performance or a future need to replace the solar concentrator with new units. The embodiments of this invention use total internal reflection to direct the focused sun light towards the exit surface and the PV cell. This requires a precise positioning of the reflectors and the steps relative to the focusing elements to achieve the TIR over the acceptance angle of the concentrator. Therefore the concentrators of this invention are relatively cost-effective and easier to manufacture as they can be made by, for example, by plastic injection molding on a large scale with no need for any reflective coatings. Furthermore, as the present solar concentrator is a single piece or monolithic there are no alignment and assembly critical issues of the type that can arise with multiple component solar concentrators or optical elements.

There can be numerous variations to the embodiments described above. The foregoing description is by way of example only and is not to be construed to limit the scope of the invention, as defined by the following claims.

MONOLITHIC PHOTOVOLTAIC SOLAR CONCENTRATOR

| | Item | |
|---|---|---|
| FIG. | Number | Name |
| 1 | 10 | Non-imaging solar collector apparatus |
| 5 | 10a,b | Two solar concentrators 10a, 10b |
| 1, 3 | 12 | Solar concentrator consisting of a solid, one-piece, |
| | | light transmitting optical element |
| 1 | 14 | Entry/input surface of the optical element (12) |
| 1, 2, 3 | 16 | Focusing elements |
| 2, 3, 12 | 17 | Light beams |
| 12 | 17′ | Ray |
| 1 | 18 | Input plane |
| 1 | 19 | Opposed plane |
| 1 | 20 | An axis |
| 1 | 22 | Opposed surface of optical element (12) |
| 1, 2, 3 | 24 | Light reflecting steps |
| | 25 | Reflectors |
| 2 | 26 | Output surface |
| 2 | 27 | Sag |
| 2 | 28 | NA |
| 2 | 29 | Height |
| 2 | 30 | PV Cell |
| 3 | 31 | Reference numeral |
| 3 | 32 | First planar portion |
| 3 | 34 | Second planar portion |
| 5 | 100 | two-sided linear, non-imaging solar collector |
| | | apparatus |
| 6 | 201 | Dividing plane |
| 5 | 226 | Light receiving surfaces |
| 6 | 200 | Solar collector apparatus (according to third |
| | | embodiment of invention) |
| 6 | 210 | Composite |
| 6 | 212 | Solar concentrator consisting of entry input surface |
| | 214 | NA |
| 6 | 216 | Linear, aspherical focusing elements |
| 6 | 217 | Selected light beams shown |
| 6 | 218 | Input plane |
| 6 | 226 | Light receiving region (exit surface) |
| 6 | 230 | PV Cell |
| 6 | 232 | First planar portion |
| 6 | 234 | Second planar portion |
| 7, 8 | 300 | Solar collector apparatus (according to fourth |
| | | embodiment of invention) |
| 7, 8 | 312 | Solar concentrator consisting of focusing elements |
| 7, 8 | 316 | Hyperbolic focusing elements |
| 7 | 317′ | Beam of light |
| 7 | 318 | Input plane |
| 7 | 332 | Steps |
| 7, 8 | 334 | Reflector |
| 8 | 336 | Ray bundles |
| 9 | 400 | Solar collector (according to the fifth embodiment |
| | | of invention) |
| 9 | 412 | Optical element (according to fifth embodiment of |
| | | invention) |
| 9 | 414 | First surface of optical element (412) |
| 9 | 416 | Hyperbolic focusing elements |
| 9 | 418′ | Input plane |
| 9 | 422 | Opposed surface of optical element |
| 9 | 426 | Output surface |
| 9 | 430 | A PV cell |
| 9 | 432 | Step |
| 9 | 434 | Reflector |
| 9 | 440 | Redirecting element |
| 10 | 500 | A linear solar collector apparatus (according to the |
| | | sixth embodiment of invention) |
| 10 | 512 | A linear optical element (according to sixth |
| | | embodiment of invention) |
| 10 | 514 | Entry/input surface |
| 10 | 516 | Linearly extending, transversely spaced, focusing |
| | | elements |
| 10 | 518 | A plane |
| | 520 | NA |
| 10 | 522 | Opposed surface (not shown) |
| 10 | 524 | Reflective steps |
| 10 | 526 | Output surface |
| 10 | 540 | Redirecting element |
| 11 | 600 | Solar collector apparatus (according to seventh |
| | | embodiment of invention) |
| 11 | 612 | A solar concentrator consisting of focusing |
| | | elements |
| 11 | 614 | Entry/input surface |
| 11 | 616 | Contiguous rows of focusing elements |
| 11 | 620 | An axis |
| 11 | 622 | Opposed surface |
| 11 | 624 | Light reflecting steps |
| 11 | 626 | Output surface |
| 11 | 640 | Redirecting element |
| 12 | 800 | Solar collector apparatus (according to ninth |
| | | embodiment of invention) |
| 12 | 812 | Optical element |
| 12 | 814 | First surface |
| 12 | 826 | Output surface |
| 12 | 830 | Horizontally-oriented PV cell |
| 12 | 832 | Step |
| 12 | 836 | Lateral surface |
| 12 | 900 | Solar collector apparatus (according to tenth |
| | | embodiment of invention) |
| 12 | 912 | |
| 12 | 913 | |
| 12 | 922 | |
| 12 | 926 | Output surface |
| 12 | 917 | Beam |
| 12 | 930 | PV Cell |
| 12 | 936 | Lateral surface |

1. A photovoltaic solar collector and concentration apparatus comprising:
a non-imaging solar concentrator consisting of a solid, one-piece, light transmitting component having (i) an input surface including a plurality of sunlight collecting and focusing elements (ii) a stepped surface opposed to the input surface defining a series of sunlight reflectors corresponding to the focusing elements, and (iii) a concentrated light output surface; and
a photovoltaic solar cell optically coupled to the concentrator and wherein the impinging sunlight received by the focusing elements within an angle of acceptance is focused onto the light reflectors positioned to direct the focused sunlight therefrom towards the photovoltaic solar cell via total internal reflection either (a) directly and without an additional reflection from the input surface or (b) indirectly via an additional optical redirecting element.

2. The apparatus of claim 1, wherein the reflectors do not have a mirror coating.

3. The apparatus of claim 1, wherein the focusing elements are made of a material chosen from glass and plastic.

4. The apparatus of claim 1, wherein the optical element is made of a plastic chosen from acrylic, silicone and polycarbonate.

5. The apparatus of claim 1, wherein the focusing elements are spherical, aspherical, parabolic, elliptical, free form, or a combination thereof.

6. The apparatus of claim 1, wherein the reflectors are flat or curved, elliptical, parabolic, hyperbolic, or free form.

7. The apparatus of claim 1 wherein the stepped surface includes a plurality of reflective steps between the reflectors.

8. The apparatus of claim 7, wherein the focusing elements and plurality of reflective steps form concentric rings about an axis central and normal to the concentrated light receiving region.

9. A photovoltaic solar collector and concentration apparatus comprising:
a non-imaging solar concentrator consisting of a solid, one-piece, light transmitting component having a plurality of focusing elements coupled to a plurality of TIR reflecting surfaces;
a photovoltaic solar cell optically coupled to the concentrator to receive focused light directly from the TIR reflecting surfaces.
